(19) United States
(12) Patent Application Publication
(10) Pub. No.: US 2025/0069650 A1
(43) Pub. Date: Feb. 27, 2025

(54) THREE-PORT SRAM CIRCUIT

(71) Applicant: Shanghai Huali Integrated Circuit Corporation, Shanghai (CN)

(72) Inventors: Pinhan CHEN, Shanghai (CN); Gang LI, Shanghai (CN)

(73) Assignee: Shanghai Huali Integrated Circuit Corporation, Shanghai (CN)

(21) Appl. No.: 18/744,498

(22) Filed: Jun. 14, 2024

(30) Foreign Application Priority Data
Aug. 25, 2023 (CN) 202311085606.5

(51) Int. Cl. G11C 11/412; G11C 11/419; H10B 10/00

(52) U.S. Cl. CPC G11C 11/412; G11C 11/419; H10B 10/12; H10B 10/18

(57) ABSTRACT

The present application discloses a three-port SRAM circuit, which is formed by adding two read ports to a six-transistor single-port SRAM circuit. Storage states of a first node and a second node of the six-transistor single-port SRAM circuit are opposite, so that a third P-type transistor with a gate terminal thereof corresponding to the first node and a fifth N-type transistor with a gate terminal thereof corresponding to the second node can be on/off synchronously. When a sixth N-type transistor and a fourth P-type transistor are both on, a port C bit line and a port B bit line can be held/discharge synchronously, so as to facilitate a system operating a peripheral circuit simultaneously when reading ports B and C at high speeds.

### CROSS-REFERENCES TO RELATED APPLICATIONS

This application claims priority to Chinese patent application No. 202311085606.5, filed on Aug. 25, 2023 at CNIPA, and entitled “THREE-PORT SRAM CIRCUIT”, the disclosure of which is incorporated herein by reference in entirety.

### TECHNICAL FIELD

The present application relates to a semiconductor circuit design technology, and in particular, to a three-port static random access memory (SRAM) circuit.

### BACKGROUND

Among volatile memories, a static random access memory (SRAM) is featured by low power consumption and high performance, and a dynamic random access memory (DRAM) is featured by low costs and a large storage capacity.

In order to improve system performance, various memory circuits are often embedded in the current system on chip (SOC). Particularly, a static random access memory (SRAM) circuit, which is compatible with the current CMOS process, is usually used in a level 1/level 2 cache (L1/L2 cache) of a computing chip, and naturally becomes the first choice for embedded memories.

An existing six-transistor single-port (6T SP) SRAM is shown in FIG. 1, where data states are stored by a first node nl and a second node n2. In the case of the word line WL=1, a first P-type transistor P1 and a second P-type transistor P2 are on, and writing or reading is performed through a first bit line BL1 and a second bit line BL2. The first bit line BLI and the second BL2 are located at the same port (1 port), which is capable of writing and reading with a modest operation speed.

### BRIEF SUMMARY

This application provides a three-port SRAM circuit, so as to facilitate a system operating a peripheral circuit simultaneously when reading ports B and C at high speeds.

The three-port SRAM circuit provided by the present application includes a first P-type transistor P1, a second P-type transistor P2, a third P-type transistor P3, a fourth P-type transistor P4, a first N-type transistor N1, a second N-type transistor N2, a third N-type transistor N3, a fourth N-type transistor N4, a fifth N-type transistor N5, and a sixth N-type transistor N6, wherein
source terminals of the first P-type transistor Pl and the second P-type transistor P2 are connected to an operating voltage Vdd;
a gate terminal of the first P-type transistor P1, a drain terminal of the second P-type transistor P2, a gate terminal of the first N-type transistor N1, a drain terminal of the second N-type transistor N2, and a gate terminal of the fifth N-type transistor N5 are connected together to a second node n2;
a gate terminal of the second P-type transistor P2, a drain terminal of the first P-type transistor P1, a gate terminal of the second N-type transistor N2, a drain terminal of the first N-type transistor N1, and a gate terminal of the third P-type transistor P3 are connected together to a first node n1;
gate terminals of the third N-type transistor N3 and the fourth N-type transistor N4 are connected to a word line A A-WL;
source and drain terminals of the third N-type transistor N3 are respectively connected to the first node nl and a first bit line BL1;
source and drain terminals of the fourth N-type transistor N4 are respectively connected to the second node n2 and a second bit line BL2;
a gate terminal of the fourth P-type transistor P4 is connected to a word line C C-WL, and source and drain terminals of same are respectively connected to a source terminal of the third P-type transistor P3 and a port C bit line;

a gate terminal of the sixth N-type transistor N6 is connected to a word line B B-WL, and source and drain terminals of same are respectively connected to a drain terminal of the fifth N-type transistor N5 and a port B bit line;
a source terminal of the first N-type transistor N1, a source terminal of the second N-type transistor N2, a drain terminal of the third P-type transistor P3, and a source terminal of the fifth N-type transistor N5 are connected to a common ground Vss.

In some examples, the word line A A-WL, the first bit line BLI, and the second bit line BL2 belong to a port A;
the word line C C-WL and the port C bit line belong to a port C;
the word line B B-WL and the port B bit line belong to a port B.

In some examples, the third P-type transistor P3 and the fourth P-type transistor P4 are field effect transistors FETs;
the fifth N-type transistor N5 and the sixth N-type transistor N6 are field effect transistors FETs.

In some examples, the third P-type transistor P3, the fourth P-type transistor P4, the fifth N-type transistor N5, and the sixth N-type transistor N6 are junction field effect transistors FETs or metal oxide semiconductor field effect transistors FETs.

In some examples, the first P-type transistor Pl and the second P-type transistor P2 are PMOS transistors;
the first N-type transistor N1, the second N-type transistor N2, the third N-type transistor N3, and the fourth N-type transistor N4 are NMOS transistors.

In some examples, the source terminal of the fourth P-type transistor P4 is connected to the port C bit line, and the drain terminal of same is connected to the source terminal of the third P-transistor P3;
the source terminal of the sixth N-type transistor N6 is connected to the drain terminal of the fifth N-type transistor N5, and the drain terminal of same is connected to the port B bit line.

In some examples, the first P-type transistor PI is located on the left side of the second P-type transistor P2;
the first N-type transistor NI and the third N-type transistor N3 are located on the left side of the first P-type transistor P1, and the first N-type transistor NI is located on the front side of the third N-type transistor N3;
the third P-type transistor P3 and the fourth P-type transistor P4 are located on the left side of the first N-type transistor NI and the third N-type transistor N3, and the third P-type transistor P3 is located on the front side of the fourth P-type transistor P4;
the second N-type transistor N2 and the fourth N-type transistor N4 are located on the right side of the second P-type transistor P2, and the second N-type transistor N2 is located on the rear side of the fourth N-type transistor N4;
the fifth N-type transistor N5 and the sixth N-type transistor N6 are located on the right side of the second N-type transistor N2 and the fourth N-type transistor N4, and the fifth N-type transistor N5 is located on the rear side of the sixth N-type transistor N6.

In some examples, center lines of gate polysilicon of the first P-type transistor PI, the first N-type transistor N1, the third P-type transistor P3, the fourth N-type transistor N4, the sixth N-type transistor N6 in the horizontal direction are on the same straight line;
center lines of gate polysilicon of the second P-type transistor P2, the third N-type transistor N3, the fourth P-type transistor P4, the second N-type transistor N2, and the fifth N-type transistor N5 in the horizontal direction are on the same straight line.

In the three-port SRAM circuit of the present application, storage states of the first node nl and the second node n2 of a six-transistor single-port (6T SP) SRAM circuit are opposite, so that the third P-type transistor P3 with the gate terminal thereof corresponding to the first node nl and the fifth N-type transistor N5 with the gate terminal thereof corresponding to the second node n2 can be on/off synchronously. When the system is in a read state, that is, when the sixth N-type transistor N6 and the fourth P-type transistor P4 are both on, the port C bit line C-BL and the port B bit line B-BL can be held/discharge synchronously, so as to facilitate the system operating the peripheral circuit simultaneously when reading ports B and C at high speeds. The system can operate the peripheral circuit without the use of an inverter for determining a storage state.

### BRIEF DESCRIPTION OF THE DRAWINGS

In order to more clearly explain the technical solutions of the present application, the drawings required to be used in the present application will be briefly described below. It is obvious that the drawings described below are merely some embodiments of the present application, and those skilled in the art could also obtain other drawings on the basis of these drawings without the practice of inventive effort.

FIG. 1 is a circuit diagram of an existing 6T SP SRAM;

FIG. 2 is a circuit diagram of an embodiment of a three-port SRAM circuit of the present application;

FIG. 3 is a high-speed read port held state of an embodiment of the three-port SRAM of the present application;

FIG. 4 is a high-speed read port discharge state of an embodiment of the three-port SRAM of the present application; and

FIG. 5 is a chip layout of an embodiment of the three-port SRAM of the present application.

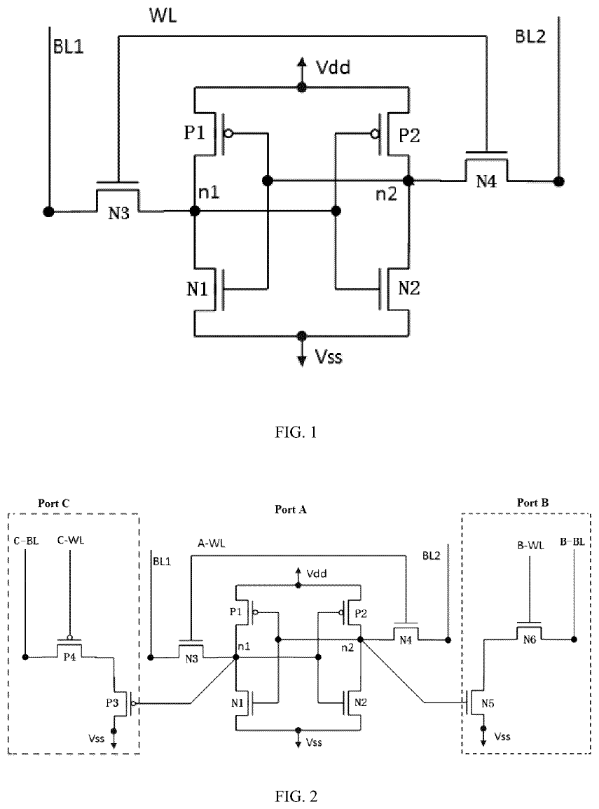

### DETAILED DESCRIPTION OF THE DISCLOSURE

The technical solutions in the embodiments of the present application will be clearly and completely described below in conjunction with the drawings. Obviously, the described embodiments are only part of the embodiments of the present application, rather than all of the embodiments. Based on the embodiments in the present application, all other embodiments obtained by those skilled in the art without the practice of inventive effort shall fall into the protection scope of the present application.

The terms such as “first” and “second” used in the present application do not indicate any order, quantity, or importance, but are only used to distinguish different constituent parts. The terms such as “include” or “comprise” means that the components or objects in front of these terms cover the components or objects listed after the terms and equivalents thereof, but does not exclude other components or objects. The terms such as “connection” or “coupling” are not limited to physical or mechanical connections, but may include electrical connections, whether direct or indirect. The terms such as “upper”, “lower”, “left”, and “right” are only used to represent relative positional relationships, which may be changed accordingly after absolute positions of the described objects are changed.

It should be noted that the embodiments or features in the embodiments of the present application can be combined with each other in the case of no conflicts.

### Embodiment I

Referring to FIG. 2, a three-port static random access memory (SRAM) circuit includes a first P-type transistor P1, a second P-type transistor P2, a third P-type transistor P3, a fourth P-type transistor P4, a first N-type transistor N1, a second N-type transistor N2, a third N-type transistor N3, a fourth N-type transistor N4, a fifth N-type transistor N5, and a sixth N-type transistor N6.

Source terminals of the first P-type transistor Pl and the second P-type transistor P2 are connected to an operating voltage Vdd.

A gate terminal of the first P-type transistor P1, a drain terminal of the second P-type transistor P2, a gate terminal of the first N-type transistor N1, a drain terminal of the second N-type transistor N2, and a gate terminal of the fifth N-type transistor N5 are connected together to a second node n2.

A gate terminal of the second P-type transistor P2, a drain terminal of the first P-type transistor P1, a gate terminal of the second N-type transistor N2, a drain terminal of the first N-type transistor N1, and a gate terminal of the third P-type transistor P3 are connected together to a first node n1.

Gate terminals of the third N-type transistor N3 and the fourth N-type transistor N4 are connected to a word line A A-WL.

Source and drain terminals of the third N-type transistor N3 are respectively connected to the first node nl and a first bit line BL1.

Source and drain terminals of the fourth N-type transistor N4 are respectively connected to the second node n2 and a second bit line BL2.

A gate terminal of the fourth P-type transistor P4 is connected to a word line C C-WL, and source and drain terminals of same are respectively connected to a source terminal of the third P-type transistor P3 and a port C bit line C-BL.

A gate terminal of the sixth N-type transistor N6 is connected to a word line B B-WL, and source and drain terminals of same are respectively connected to a drain terminal of the fifth N-type transistor N5 and a port B bit line B-BL.

A source terminal of the first N-type transistor N1, a source terminal of the second N-type transistor N2, a drain terminal of the third P-type transistor P3, and a source terminal of the fifth N-type transistor N5 are connected to a common ground Vss.

The word line A A-WL, the first bit line BLI, and the second bit line BL2 belong to a port A.

The word line C C-WL and the port C bit line belong to a port C.

The word line B B-WL and the port B bit line belong to a port B.

The three-port SRAM circuit of Embodiment I is a ten-transistor three-port (10T 3P) SRAM structure, which is formed by adding two read ports to a six-transistor single-port (6T SP) SRAM circuit. The port A is a 6T single port (6T SP) in the middle of the circuit, which is capable of writing and reading with a modest operation speed. The port B is a high-speed read port including two N-type transistors, the fifth N-type transistor N5 and the sixth N-type transistor N6, where the gate terminal of the fifth N-type transistor N5 is connected to the second node n2 and used for high-speed reading via the port B bit line B-BL. The port C is a high-speed read port including two P-transistors, the third P-transistor P3 and the fourth P-transistor P4, where the gate terminal of the third P-transistor P3 is connected to the first node nl and used for high-speed reading via the port C bit line C-BL.

If n1=1 and n2-0, the word line B (B-WL)=1, then the sixth N-type transistor N6 is on, the port B bit line B-BL is held, and the port B is read as 1;

if n1=0 and n2=1, the word line B (B-WL)=1, then the sixth N-type transistor N6 is on, the port B bit line B-BL discharges, and the port B is read as 0;

if n1=1 and n2=0, the word line C (C-WL)=1, then the fourth P-type transistor P4 is on, the port C bit line C-BL is held, and the port C is read as 1; and

if n1=0 and n2=1, the word line C (C-WL)=0, then the fourth P-type transistor P4 is on, the port C bit line C-BL is held, and the port C is read as 0.

The port C and the port B are respectively connected to the first node nl and the second node n2 inside the 6T single port (6T SP), exactly forming a complementary match pattern to achieve the function of simultaneous on and off.

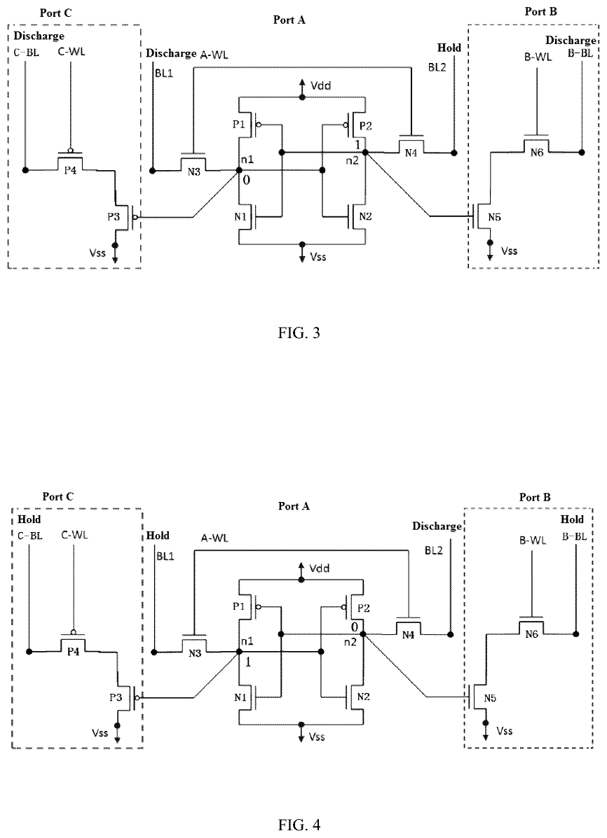

When n1=0, then n2=1 (an internal data storage state of 6T SP is 0), the connection corresponds to the gate terminal of the fifth N-type transistor N5 to turn on the fifth N-type transistor N5, and the connection corresponds to the gate terminal of the third P-type transistor P3 to turn on the third P-type transistor P3. The port C and the port B read stored data 0 at the same time, as shown in Table 1 and FIG. 3.

TABLE 1

| | Write/read | | Read port | Word line | Bit line | Read |
|---|---|---|---|---|---|---|
| Port | capability | Storage state | gate | operation | operation | state |
| Port A | Write/read | Stored data is 0 | | A-WL = 1 | BL1 discharges | Read 0 |
| | | (n1 = 0, n2 = 1) | | Port on | BL2 is held | |
| Port B | Read only | | N5 gate | B-WL = 1 | B-BL discharges | Read 0 |
| | | | terminal = 1 | Port on | | |
| | | | (on) | | | |
| Port C | Read only | | P3 gate | C-WL = 0 | C-BL discharges | Read 0 |
| | | | terminal = 0 | Port on | | |
| | | | (on) | | | |

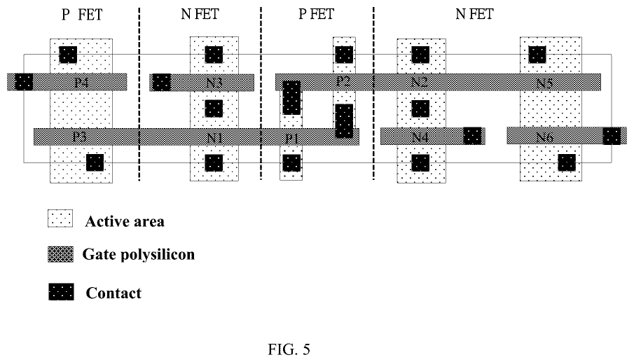

When n1=1, then n2=0 (an internal data storage state of 6T SP is 1), the connection corresponds to the gate terminal of the fifth N-type transistor N5 to turn off the fifth N-type transistor N5, and the connection corresponds to the gate terminal of the third P-type transistor P3 to turn off the third P-type transistor P3. The port C and the port B read stored data 1 at the same time, as shown in Table 2 and FIG. 4.

TABLE 2

| | Write/read | | Read port | Word line | Bit line | Read |
|---|---|---|---|---|---|---|
| Port | capability | Storage state | gate | operation | operation | state |
| Port A | Write/read | Stored data is | | A-WL = 1 | BL1 is held | Read 1 |
| | | 1 (n1 = 1, | | Port on | BL2 discharges | |
| | | n2 = 0) | | | | |
| Port B | Read only | | N5 gate | B-WL = 1 | B-BL is held | Read 1 |
| | | | terminal = 0 | Port on | | |
| | | | (off) | | | |
| Port C | Read only | | P3 gate | C-WL = 0 | C-BL is held | Read 1 |
| | | | terminal = 1 | Port on | | |
| | | | (off) | | | |

In the three-port SRAM circuit of Embodiment I, storage states of the first node n1 and the second node n2 of the six-transistor single-port (6T SP) SRAM circuit are opposite, so that the third P-type transistor P3 with the gate terminal thereof corresponding to the first node n1 and the fifth N-type transistor N5 with the gate terminal thereof corresponding to the second node n2 can be on/off synchronously. When the system is in a read state, that is, when the sixth N-type transistor N6 and the fourth P-type transistor P4 are both on, the port C bit line C-BL and the port B bit line B-BL can be held/discharge synchronously, so as to facilitate the system operating the peripheral circuit simultaneously when reading ports B and C at high speeds. The system can operate the peripheral circuit without the use of an inverter for determining a storage state.

### Embodiment II

In the three-port SRAM circuit of Embodiment I, the third P-type transistor P3 and the fourth P-type transistor P4 are field effect transistors FETs.

The fifth N-type transistor N5 and the sixth N-type transistor N6 are field effect transistors FETs.

In some examples, the third P-type transistor P3, the fourth P-type transistor P4, the fifth N-type transistor N5, and the sixth N-type transistor N6 are junction field effect transistors JFETs or metal oxide semiconductor field effect transistors MOSFETs.

In some examples, the first P-type transistor Pl and the second P-type transistor P2 are PMOS transistors.

The first N-type transistor N1, the second N-type transistor N2, the third N-type transistor N3, and the fourth N-type transistor N4 are NMOS transistors.

In some examples, the source terminal of the fourth P-type transistor P4 is connected to the port C bit line, and the drain terminal of same is connected to the source terminal of the third P-transistor P3.

The source terminal of the sixth N-type transistor N6 is connected to the drain terminal of the fifth N-type transistor N5, and the drain terminal of same is connected to the port B bit line.

In the three-port SRAM circuit of Embodiment II, the port B employs two P-type field effect transistor FET assemblies, and the port C employs two N-type field effect transistor FET assemblies.

### Embodiment III

The three-port SRAM circuit of Embodiment I, referring to FIG. 5, has a chip layout structure as follows:

The first P-type transistor PI is located on the left side of the second P-type transistor P2.

The first N-type transistor N1 and the third N-type transistor N3 are located on the left side of the first P-type transistor P1, and the first N-type transistor N1 is located on the front side of the third N-type transistor N3.

The third P-type transistor P3 and the fourth P-type transistor P4 are located on the left side of the first N-type transistor N1 and the third N-type transistor N3, and the third P-type transistor P3 is located on the front side of the fourth P-type transistor P4.

The second N-type transistor N2 and the fourth N-type transistor N4 are located on the right side of the second P-type transistor P2, and the second N-type transistor N2 is located on the rear side of the fourth N-type transistor N4.

The fifth N-type transistor N5 and the sixth N-type transistor N6 are located on the right side of the second N-type transistor N2 and the fourth N-type transistor N4, and the fifth N-type transistor N5 is located on the rear side of the sixth N-type transistor N6.

In some examples, center lines of gate polysilicon of the first P-type transistor P1, the first N-type transistor N1, the third P-type transistor P3, the fourth N-type transistor N4, the sixth N-type transistor N6 in the horizontal direction (in the left and right directions) are on the same straight line.

Center lines of gate polysilicon of the second P-type transistor P2, the third N-type transistor N3, the fourth P-type transistor P4, the second N-type transistor N2, and the fifth N-type transistor N5 in the horizontal direction (in the left and right directions) are on the same straight line.

The above descriptions are merely examples of the embodiments of the present application and are not intended to limit the present application. Any modifications, equivalent substitutions, improvements, etc. made within the spirit and principles of the present application shall be included within the protection scope of the present application.

What is claimed is:

1. A three-port SRAM circuit, comprising a first P-type transistor (P1), a second P-type transistor (P2), a third P-type transistor (P3), a fourth P-type transistor (P4), a first N-type transistor (N1), a second N-type transistor (N2), a third N-type transistor (N3), a fourth N-type transistor (N4), a fifth N-type transistor (N5), and a sixth N-type transistor (N6), wherein
source terminals of the first P-type transistor (P1) and the second P-type transistor (P2) are connected to an operating voltage (Vdd);
a gate terminal of the first P-type transistor (P1), a drain terminal of the second P-type transistor (P2), a gate terminal of the first N-type transistor (N1), a drain terminal of the second N-type transistor (N2), and a gate terminal of the fifth N-type transistor (N5) are connected together to a second node (n2);
a gate terminal of the second P-type transistor (P2), a drain terminal of the first P-type transistor (P1), a gate terminal of the second N-type transistor (N2), a drain terminal of the first N-type transistor (N1), and a gate terminal of the third P-type transistor (P3) are connected together to a first node (n1);
gate terminals of the third N-type transistor (N3) and the fourth N-type transistor (N4) are connected to a word line A (A-WL);
source and drain terminals of the third N-type transistor (N3) are respectively connected to the first node (n1) and a first bit line (BL1);
source and drain terminals of the fourth N-type transistor (N4) are respectively connected to the second node (n2) and a second bit line (BL2);
a gate terminal of the fourth P-type transistor (P4) is connected to a word line C (C-WL), and source and drain terminals of same are respectively connected to a source terminal of the third P-type transistor (P3) and a port C bit line;
a gate terminal of the sixth N-type transistor (N6) is connected to a word line B (B-WL), and source and drain terminals of same are respectively connected to a drain terminal of the fifth N-type transistor (N5) and a port B bit line; and
a source terminal of the first N-type transistor (N1), a source terminal of the second N-type transistor (N2), a drain terminal of the third P-type transistor (P3), and a source terminal of the fifth N-type transistor (N5) are connected to a common ground (Vss).

2. The three-port SRAM circuit according to claim 1, wherein
the word line A (A-WL), the first bit line (BL1), and the second bit line (BL2) belong to a port A;
the word line C (C-WL) and the port C bit line belong to a port C; and
the word line B (B-WL) and the port B bit line belong to a port B.

3. The three-port SRAM circuit according to claim 1, wherein
the third P-type transistor (P3) and the fourth P-type transistor (P4) are field effect transistors; and
the fifth N-type transistor (N5) and the sixth N-type transistor (N6) are field effect transistors;

4. The three-port SRAM circuit according to claim 1, wherein
the third P-type transistor (P3), the fourth P-type transistor (P4), the fifth N-type transistor (N5), and the sixth N-type transistor (N6) are junction field effect transistors or metal oxide semiconductor field effect transistors.

5. The three-port SRAM circuit according to claim 1, wherein
the first P-type transistor (P1) and the second P-type transistor (P2) are PMOS transistors; and
the first N-type transistor (N1), the second N-type transistor (N2), the third N-type transistor (N3), and the fourth N-type transistor (N4) are NMOS transistors.

6. The three-port SRAM circuit according to claim 1, wherein
the source terminal of the fourth P-type transistor (P4) is connected to the port C bit line, and the drain terminal of same is connected to the source terminal of the third P-transistor (P3); and
the source terminal of the sixth N-type transistor (N6) is connected to the drain terminal of the fifth N-type transistor (N5), and the drain terminal of same is connected to the port B bit line.

7. The three-port SRAM circuit according to claim 1, wherein a chip layout structure thereof is as follows:
the first P-type transistor (P1) is located on the left side of the second P-type transistor (P2);
the first N-type transistor (N1) and the third N-type transistor (N3) are located on the left side of the first P-type transistor (P1), and the first N-type transistor (N1) is located on the front side of the third N-type transistor (N3);
the third P-type transistor (P3) and the fourth P-type transistor (P4) are located on the left side of the first N-type transistor (N1) and the third N-type transistor (N3), and the third P-type transistor (P3) is located on the front side of the fourth P-type transistor (P4);
the second N-type transistor (N2) and the fourth N-type transistor (N4) are located on the right side of the second P-type transistor (P2), and the second N-type transistor (N2) is located on the rear side of the fourth N-type transistor (N4); and
the fifth N-type transistor (N5) and the sixth N-type transistor (N6) are located on the right side of the second N-type transistor (N2) and the fourth N-type transistor (N4), and the fifth N-type transistor (N5) is located on the rear side of the sixth N-type transistor (N6).

8. The three-port SRAM circuit according to claim 7, wherein the chip layout structure thereof is as follows:
center lines of gate polysilicon of the first P-type transistor (P1), the first N-type transistor (N1), the third P-type transistor (P3), the fourth N-type transistor (N4), the sixth N-type transistor (N6) in the horizontal direction are on the same straight line; and
center lines of gate polysilicon of the second P-type transistor (P2), the third N-type transistor (N3), the fourth P-type transistor (P4), the second N-type transistor (N2), and the fifth N-type transistor (N5) in the horizontal direction are on the same straight line.
